(19) United States
(12) Patent Application Publication
(10) Pub. No.: US 2020/0152800 A1
(43) Pub. Date: May 14, 2020

(54) CMOS INVERTER AND ARRAY SUBSTRATE

(71) Applicant: Shenzhen China Star Optoelectronics Semiconductor Display Technology Co., Ltd, Shenzhen, Guangdong (CN)

(72) Inventors: Xingyu ZHOU, Shenzhen, Guangdong (CN); Yuanjun HSU, Shenzhen, Guangdong (CN); Jangsoon IM, Shenzhen, Guangdong (CN); Yuanchun WU, Shenzhen, Guangdong (CN); Poyen LU, Shenzhen, Guangdong (CN); Boru YANG, Shenzhen, Guangdong (CN); Changdong CHEN, Shenzhen, Guangdong (CN); Chuan LIU, Shenzhen, Guangdong (CN)

(73) Assignee: Shenzhen China Star Optoelectronics Semiconductor Display Technology Co., Ltd., Shenzhen, Guandong (CN)

(21) Appl. No.: 15/743,990

(22) PCT Filed: Nov. 15, 2017
(86) PCT No.: PCT/CN2017/110989

§ 371 Date: Jan. 11, 2018

(30) Foreign Application Priority Data
Oct. 10, 2017 (CN) 201710937121.2

(51) Int. Cl. H01L 29/786; H01L 27/12

(52) U.S. Cl. CPC H01L 29/78678; H01L 27/1225; H01L 27/1251; H01L 29/78696; H01L 29/7869

(57) ABSTRACT

The present invention provides a CMOS inverter and array substrate. The CMOS inverter comprises a P-type low-temperature polysilicon thin film transistor electrically coupled to a N-type metal-oxide thin film transistor; the P-type low-temperature polysilicon thin film transistor and the N-type metal-oxide thin film transistor satisfy the relationship:

$${C}_{n} \frac{{W}_{n}}{{L}_{n}} {μ}_{n} = {C}_{P} \frac{{W}_{P}}{{L}_{P}} {μ}_{P} ;$$

wherein, Cₙ and C_{P} is a gate-insulating-layer capacitance of the N-type metal oxide TFT and the P-type low-temperature polysilicon TFT, respectively,

$$\frac{{W}_{n}}{{L}_{n}} and \frac{{W}_{P}}{{L}_{P}}$$

is a channel width-length ratio of the N-type metal-oxide TFT and the P-type low-temperature polysilicon TFT, respectively, μₙ and μ_{P} is a mobility of the N-type metal-oxide TFT and P-type low-temperature polysilicon TFT. The performance of the CMOS inverter could be improved and the manufacturing complexity and cost of the CMOS could be reduced.

### RELATED APPLICATIONS

The present application is a National Phase of International Application Number PCT/CN2017/110989 filed on Nov. 15, 2017 and claims the priority of China Application No. 201710937121.2, filed on Oct. 10, 2017.

### FIELD OF THE DISCLOSURE

The disclosure relates to a display technical field, and more particularly to a CMOS inverter and array substrate.

### BACKGROUND

With the development of display technologies, the flat panel display devices, including Liquid Crystal Display (LCD) and Organic Light Emitting Display (OLED), have become the most commonly used display devices, and are widely used in variety of consuming electronic products, such as mobile phone, television, personal digital assistor, digital camera, notebook or desktop.

CMOS (Complementary Metal Oxide Semiconductor) inverters, are elements usually used in flat panel display devices and functioned to receive an input signal and output an output signal logically inverted from the input signal.

The CMOS inverter used nowadays usually comprises a N-type thin film transistor (TFT) and a P-type TFT. Ideally, both the N-type TFT and the P-type TFT are supposed to be metal-oxide TFT, such as IGZO TFT. However, the IGZO TFT can only be made as a N-type unipolar semiconductor, and, therefore, difficulties occurred while designing logical circuit basing on IGZO TFT due to lacking of a P-type semiconductor.

The researches on IGZO TFT logical circuit designing nowadays could be roughly divided into two categories. The first category is to make a Pseudo-CMOS to accomplish an inverter by using IGZO TFT only. When the Pseudo-CMOS is designed, different threshold voltages are necessary for two IGZO TFTs. Therefore, depletion mode IGZO TFT and enhancement mode IGZO TFT must be made in one sample. The technologies, such as dual-gate structure, dual active layer structure and extra light on the IGZO TFT, are developed for making the Pseudo-CMOS therefore. However, even in the inverters made by these technologies, the problems of great static power consumption and low noise endurance of the Pseudo-CMOS are still existed. The second category provides mixing-type CMOS design, that is, the P-type TFT is accomplished by using semiconductor materials other than metal oxide. In the previous mixing-type CMOS designs, the materials used to form the P-type TFT is two-dimensional carbon nanotube (CNT) material or organic semiconductor material. However, a part of the CNT material is always metallized during manufacturing process, and the organic semiconductor material is with low mobility and sensitive to water and oxygen in the environment, so that the stability of the P-type TFT in the mixing-type CMOS is extreme poor.

### SUMMARY

The object of the present invention is to provide a CMOS inverter to increase the performance of the CMOS inverter and reduce the manufacturing complexity and cost of the CMOS inverter.

Another object of the present invention is to provide an array substrate to increase the performance of the CMOS inverter and reduce the manufacturing complexity and cost of the CMOS inverter.

To achieve the objects described above, the present invention provides a CMOS inverter, comprising: a P-type low-temperature polysilicon thin film transistor electrically coupled to a N-type metal-oxide thin film transistor;
wherein, the P-type low-temperature polysilicon thin film transistor and the N-type metal-oxide thin film transistor satisfy the relationship below:

$${C}_{n} \frac{{W}_{n}}{{L}_{n}} {μ}_{n} = {C}_{P} \frac{{W}_{P}}{{L}_{P}} {μ}_{P} ,$$

wherein, Cₙ is a gate-insulating-layer capacitance of the N-type metal oxide thin film transistor, C_{P} is a gate-insulating-layer capacitance of the P-type low-temperature polysilicon thin film transistor,

$$\frac{{W}_{n}}{{L}_{n}}$$

is a channel width-length ratio of the N-type metal-oxide thin film transistor,

$$\frac{{W}_{P}}{{L}_{P}}$$

is the channel width-length ratio of the P-type low-temperature polysilicon thin film transistor, μₙ is a mobility of the N-type metal-oxide thin film transistor, and μ_{P} is the mobility of P-type low-temperature polysilicon thin film transistor.

A gate of the P-type low-temperature polysilicon thin film transistor and a gate of the N-type metal-oxide thin film transistor both are coupled to receive an input signal;
one of a source of the P-type low-temperature polysilicon thin film transistor and a source of the N-type metal-oxide thin film transistor is coupled to ground, and another one of the source of the P-type low-temperature polysilicon thin film transistor and the source of the N-type metal-oxide thin film transistor is coupled to a voltage source; and
a drain of the P-type low-temperature polysilicon thin film transistor and a drain of the N-type metal-oxide thin film transistor both provide an output signal.

The CMOS inverter comprises: a substrate; a first semiconducting layer formed above the substrate; a first gate insulating layer covering the first semiconducting layer and the substrate; a first metal layer formed above the first gate insulating layer; a second gate insulating layer covering the first metal layer and the first gate insulating layer; a second semiconducting layer formed above the second gate insulating layer; and a second metal layer formed above the second semiconducting layer and the second gate insulating layer.

The first semiconducting layer is a semiconducting layer of the P-type low-temperature polysilicon thin film transistor, and the second semiconducting layer is a semiconducting layer of the N-type metal-oxide thin film transistor.

The first metal layer comprises: a first gate and a second gate disposed at intervals, wherein the first gate is disposed directly opposite to the first semiconducting layer and the second gate is disposed directly opposite to the second semiconducting layer; and
the first gate is a gate of the P-type low-temperature polysilicon thin film transistor, and the second gate is a gate of the N-type metal-oxide thin film transistor.

A first through hole and a second through hole penetrating through the first gate insulating layer and the second gate insulating layer are formed in the second gate insulating layer, and two terminals of the first semiconducting layer are exposed through the first through hole and the second through hole, respectively;
wherein, the second metal layer comprises: a first source and a second source disposed at intervals; and a first drain and a second drain formed between the first source and the second source; the two terminals of the first semiconducting layer are connected to the first source and the first drain through the first through hole and the second through hole, respectively, two terminals of the second semiconducting layer are connected to the second source and the second drain, respectively, and the first drain and the second drain are connected; and
the first source and the first drain are source and drain of the P-type low-temperature polysilicon thin film transistor, and the second source and the second drain are source and drain of the N-type metal-oxide thin film transistor.

A buffer layer is further formed between the first semiconducting layer and the substrate and between the first gate insulating layer and the substrate, and an etching barrier layer is formed above the second semiconducting layer between the second source and the second drain.

Materials of the first gate insulating layer and the second insulating layer each comprises at least one or combinations of silicon oxide and silicon nitride, and materials of the first metal layer and the second metal layer each comprises at least one or combinations of at least two of molybdenum, aluminum, copper, and titanium.

Material of the semiconducting layer of the N-type metal-oxide thin film transistor comprises IGZO or IZO.

The present invention further provides an array substrate comprising the CMOS inverter described above.

The present invention further provides a CMOS inverter, comprising: a P-type low-temperature polysilicon thin film transistor electrically coupled to a N-type metal-oxide thin film transistor;
wherein the P-type low-temperature polysilicon thin film transistor and the N-type metal-oxide thin film transistor satisfy the relationship below:

$${C}_{n} \frac{{W}_{n}}{{L}_{n}} {μ}_{n} = {C}_{P} \frac{{W}_{P}}{{L}_{P}} {μ}_{P}$$

wherein, Cₙ is a gate-insulating-layer capacitance of the N-type metal oxide thin film transistor, C_{P} is a gate-insulating-layer capacitance of the P-type low-temperature polysilicon thin film transistor,

$$\frac{{W}_{n}}{{L}_{n}}$$

is a channel width-length ratio of the N-type metal-oxide thin film transistor,

$$\frac{{W}_{P}}{{L}_{P}}$$

is the channel width-length ratio of the P-type low-temperature polysilicon thin film transistor, pₙ is a mobility of the N-type metal-oxide thin film transistor, and μ_{P} is the mobility of P-type low-temperature polysilicon thin film transistor;
wherein, a gate of the P-type low-temperature polysilicon thin film transistor and a gate of the N-type metal-oxide thin film transistor both are coupled to receive an input signal;
a source of the P-type low-temperature polysilicon thin film transistor is coupled to a voltage source, a source of the N-type metal-oxide thin film transistor is coupled to ground, and a drain of the P-type low-temperature polysilicon thin film transistor and a drain of the N-type metal-oxide thin film transistor both provide an output signal;
the CMOS inverter further comprises: a substrate; a first semiconducting layer formed above the substrate; a first gate insulating layer covering the first semiconducting layer and the substrate; a first metal layer formed above the first gate insulating layer; a second gate insulating layer covering the first metal layer and the first gate insulating layer; a second semiconducting layer formed above the second gate insulating layer; and a second metal layer formed above the second semiconducting layer and the second gate insulating layer;
wherein, the first semiconducting layer is a semiconducting layer of the P-type low-temperature polysilicon thin film transistor, and the second semiconducting layer is a semiconducting layer of the N-type metal-oxide thin film transistor;
wherein, the first metal layer comprises: a first gate and a second gate disposed at intervals, wherein the first gate is disposed directly opposite to the first semiconducting layer and the second gate is disposed directly opposite to the second semiconducting layer; and
the first gate is the gate of the P-type low-temperature polysilicon thin film transistor, and the second gate is the gate of the N-type metal-oxide thin film transistor.

The beneficial effect of the present invention is: the present invention provides a CMOS inverter, comprising: a CMOS inverter, comprising: a P-type low-temperature polysilicon thin film transistor electrically coupled to a N-type metal-oxide thin film transistor; wherein, the P-type low-temperature polysilicon thin film transistor and the N-type metal-oxide thin film transistor satisfy the relationship:

$${C}_{n} \frac{{W}_{n}}{{L}_{n}} {μ}_{n} = {C}_{P} \frac{{W}_{P}}{{L}_{P}} {μ}_{P} ;$$

wherein, Cₙ is a gate-insulating-layer capacitance of the N-type metal oxide thin film transistor, C_{P} is a gate-insulating-layer capacitance of the P-type low-temperature polysilicon thin film transistor,

$$\frac{{W}_{n}}{{L}_{n}}$$

is a channel width-length ratio of the N-type metal-oxide thin film transistor,

$$\frac{{W}_{P}}{{L}_{P}}$$

is the channel width-length ratio of the P-type low-temperature polysilicon thin film transistor, μₙ is a mobility of the N-type metal-oxide thin film transistor, and μ_{P} is the mobility of P-type low-temperature polysilicon thin film transistor, so that the performance of the CMOS inverter could be improved and the manufacturing complexity and cost of the CMOS could be reduced through matching the relationship between the P-type low-temperature polysilicon thin film transistor and the N-type metal-oxide thin film transistor to the relationship described above. The present invention further provides an array substrate to increase the performance of the CMOS inverter and reduce the manufacturing complexity and cost of the CMOS inverter.

### BRIEF DESCRIPTION OF THE DRAWINGS

For providing further understanding of features and technique contents of the present invention, the detailed description and drawings below are provided. However, the drawings in the description below are merely for reference and explanation, and are not for limiting the present invention.

In the drawings:

FIG. 1 is a structural diagram of the CMOS inverter of the present invention;

FIG. 2 is an equivalent circuit diagram of the CMOS inverter of the present invention.

### DETAILED DESCRIPTION OF PREFERRED EMBODIMENTS

The disclosure will be further described in detail with reference to accompanying drawings and preferred embodiments as follows.

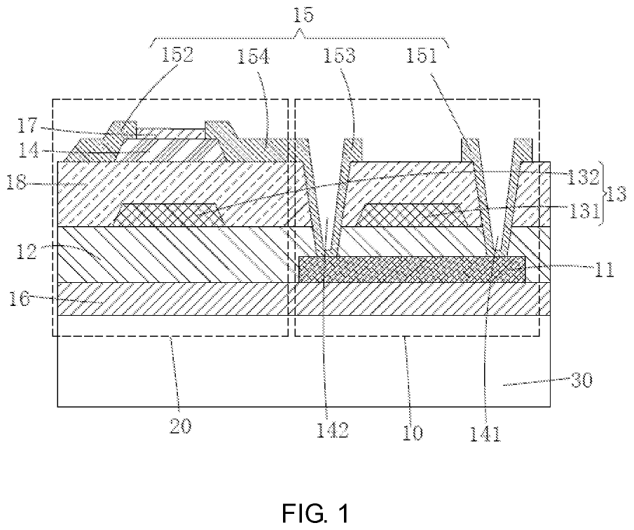

Please refer to FIG. 1. The present invention provides a CMOS inverter, comprising: a P-type low-temperature polysilicon thin film transistor 10 electrically coupled to a N-type metal-oxide thin film transistor 20;
wherein, the P-type low-temperature polysilicon thin film transistor 10 and the N-type metal-oxide thin film transistor 20 satisfy the relationship below:

$${C}_{n} \frac{{W}_{n}}{{L}_{n}} {μ}_{n} = {C}_{P} \frac{{W}_{P}}{{L}_{P}} {μ}_{P} ,$$

wherein, Cₙ is a gate-insulating-layer capacitance of the N-type metal oxide thin film transistor 20, C_{P} is a gate-insulating-layer capacitance of the P-type low-temperature

$$\frac{{W}_{n}}{{L}_{n}}$$

polysilicon thin film transistor 10, is a channel width-length ratio of the N-type

$$\frac{{W}_{P}}{{L}_{P}}$$

metal-oxide thin film transistor 20, is the channel width-length ratio of the P-type low-temperature polysilicon thin film transistor 10, pₙ is a mobility of the N-type metal-oxide thin film transistor 20, and μ_{P} is the mobility of P-type low-temperature polysilicon thin film transistor 10.

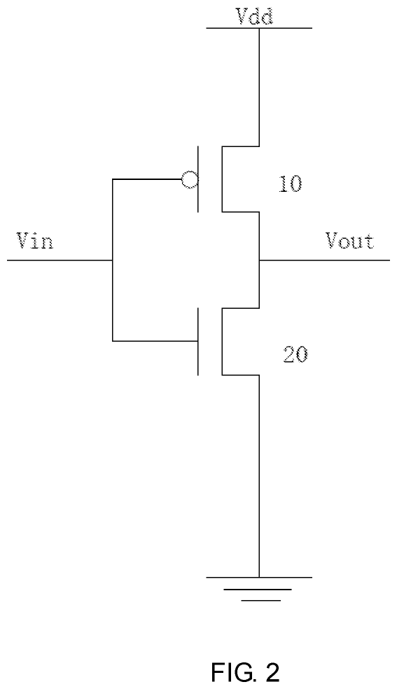

Specifically, in the CMOS inverter of the present invention as shown in FIG. 2, a gate of the P-type low-temperature polysilicon thin film transistor 10 and a gate of the N-type metal-oxide thin film transistor 20 both are coupled to receive an input signal Vin; a source of the P-type low-temperature polysilicon thin film transistor 10 is coupled to receive voltage source Vdd, and a source of N-type metal-oxide thin film transistor 20 is coupled to ground; and a drain of the P-type low-temperature polysilicon thin film transistor 10 and a drain of the N-type metal-oxide thin film transistor 20 both provide an output signal Vout.

During operation, the N-type metal-oxide thin film transistor 20 is turned on and the output signal Vout is coupled to ground through the N-type metal-oxide thin film transistor 20 when the input signal Vin is at high voltage, so that the output signal Vout is at low voltage; and the the P-type low-temperature polysilicon thin film transistor 10 is turned on and the output signal outputs the voltage source Vdd when the input signal Vin is at low voltage, so that the output signal Vout is at high voltage.

In detail, the detailed structure of the CMOS inverter in the preferred embodiment of the present invention is as follows. The CMOS inverter comprises: a substrate 30; a first semiconducting layer 11 formed above the substrate 30; a first gate insulating layer 12 covering the first semiconducting layer 11 and the substrate 30; a first metal layer 13 formed above the first gate insulating layer 12; a second gate insulating layer 18 covering the first metal layer 13 and the first gate insulating layer 12; a second semiconducting layer 14 formed above the second gate insulating layer 18; and a second metal layer 15 formed above the second semiconducting layer 14 and the second gate insulating layer 18.

Furthermore, in the embodiment described above, the first semiconducting layer 11 is a semiconducting layer of the P-type low-temperature polysilicon thin film transistor 10, and the second semiconducting layer 14 is a semiconducting layer of the N-type metal-oxide thin film transistor 20.

Furthermore, the first metal layer 13 comprises: a first gate 131 and a second gate 132 disposed at intervals, wherein the first gate 131 is disposed directly opposite to the first semiconducting layer 11, and the second gate 132 is disposed directly opposite to the second semiconducting layer 14; wherein the first gate 131 is a gate of the P-type low-temperature polysilicon thin film transistor 10, and the second gate 132 is a gate of the N-type metal-oxide thin film transistor 20.

Furthermore, a first through hole 141 and a second through hole 142 penetrating through the first gate insulating layer 12 and the second gate insulating layer 18 are formed in the second gate insulating layer 18, and two terminals of the first semiconducting layer 11 are exposed through the first through hole 141 and the second through hole 142, respectively. The second metal layer comprises: a first source 151 and a second source 152 disposed at intervals; and a first drain 153 and a second drain 154 formed between the first source 151 and the second source 152; wherein, the two terminals of the first semiconducting layer 11 are connected to the first source 151 and the first drain 153 through the first through hole 141 and the second through hole 142, respectively, two terminals of the second semiconducting layer 14 are connected to the second source 152 and the second drain 154, respectively, and the first drain 153 and the second drain 154 are connected; wherein the first source 151 and the first drain 153 are the source and the drain of the P-type low-temperature polysilicon thin film transistor 10, and the second source 152 and the second drain 154 are the source and the drain of the N-type metal-oxide thin film transistor 20.

It is noted that, a buffer layer 16 is further formed between the first semiconducting layer 11 and the substrate 30 and between the first gate insulating layer 12 and the substrate 30 of the CMOS inverter, and an etching barrier layer 17 is further formed above the second semiconducting layer 14 between the second source 152 and the second drain 154.

Preferably, the materials of the first gate insulating layer 12 and the second insulating layer 14 each comprises at least one or combinations of silicon oxide and silicon nitride, and the materials of the first metal layer 13 and the second metal layer 15 each comprises at least one or combinations of at least two of molybdenum, aluminum, copper, and titanium. The material of the semiconducting layer of the N-type metal-oxide thin film transistor 20 comprises IGZO or IZO.

Furthermore, for designing the CMOS inverter using the P-type low-temperature polysilicon thin film transistor 10 and the N-type metal-oxide thin film transistor 20, the present invention provides a design rule:

$${C}_{n} \frac{{W}_{n}}{{L}_{n}} {μ}_{n} = {C}_{P} \frac{{W}_{P}}{{L}_{P}} {μ}_{P} ,$$

Designing the COMS inverter according to the formula allows the characters of the P-type TFT and the N-type TFT to be much more matched and ensures that the P-type TFT and the N-type TFT both are operated in the saturation region, so that a better effect of the CMOS inverter can be reached.

It should be noted that the CMOS inverter of the present invention uses the low-temperature polysilicon thin film transistor as the P-type TFT and the metal-oxide thin film transistor as the N-type TFT, and combines the two kinds of TFT to form the CMOS inverter. Comparing to the CMOS inverter using only the rigid low-temperature polysilicon thin film transistors, the present invention improves the ductility of the CMOS inverter through using the metal-oxide thin film transistor as the N-type TFT, so that the CMOS inverter is more capable of requirements of flexible electronic devices. Furthermore, the CMOS inverter using only the low-temperature polysilicon thin film transistors requires complex manufacturing process including at least 9 lithographs steps and 4 doping steps, and the CMOS inverter of the present invention can be accomplished by only 6 lithographs steps and 1 doping step. Therefore, comparing with the CMOS inverter using only the low-temperature polysilicon thin film transistors nowadays, the present invention further reduces the number of lithographs steps and doping steps and simplifies the manufacturing process. Moreover, comparing with the Pseudo-CMOS inverter using only the metal-oxide thin film transistors, the present invention could reduce the static power consumption, increase the noise endurance and guarantee the production quality of the CMOS inverter.

Based on the CMOS inverter described above, the present invention further provides an array substrate comprising the CMOS inverter described above. The technique features of the CMOS inverter in the array substrate is the same as those of the CMOS inverter described above, and are not described again here.

It should be noted that, the array substrate of the present invention manufactures the low-temperature polysilicon thin film transistor and the metal-oxide thin film transistor in the same array substrate, and combines the two kinds of TFT to form the CMOS inverter, wherein the low-temperature polysilicon thin film transistor is used as the P-type TFT and the metal-oxide thin film transistor is used as the N-type TFT. Comparing with the CMOS inverter using only the rigid low-temperature polysilicon thin film transistors, the present invention improves the ductility of the CMOS inverter through using the metal-oxide thin film transistor as the N-type TFT, so that the CMOS inverter is more capable of requirements of flexible electronic devices. Furthermore, the CMOS inverter using only the low-temperature polysilicon thin film transistors requires complex manufacturing process including at least 9 lithographs steps and 4 doping steps, and the CMOS inverter of the present invention can be accomplished by only 6 lithographs steps and 1 doping step. While manufacturing the array substrate, the metal-oxide thin film transistor can be manufactured at the same time with the metal-oxide thin film transistors in the pixel array of the array substrate. Therefore, the array substrate of the present invention could improve the performance of the CMOS inverter and reduce manufacturing complexity and cost of the CMOS inverter.

According to above, the present invention provides a CMOS inverter, comprising: a CMOS inverter, comprising: a P-type low-temperature polysilicon thin film transistor electrically coupled to a N-type metal-oxide thin film transistor; wherein, the P-type low-temperature polysilicon thin film transistor and the N-type metal-oxide thin film transistor satisfy the relationship:

$${C}_{n} \frac{{W}_{n}}{{L}_{n}} {μ}_{n} = {C}_{P} \frac{{W}_{P}}{{L}_{P}} {μ}_{P} ;$$

wherein, Cₙ is a gate-insulating-layer capacitance of the N-type metal oxide thin film transistor, C_{P} is a gate-insulating-layer capacitance of the P-type low-temperature polysilicon thin film transistor,

$$\frac{{W}_{n}}{{L}_{n}}$$

is a channel width-length ratio of the N-type metal-oxide thin film transistor,

$$\frac{{W}_{P}}{{L}_{P}}$$

is the channel width-length ratio of the P-type low-temperature polysilicon thin film transistor, μₙ is a mobility of the N-type metal-oxide thin film transistor, and μ_{P} is the mobility of P-type low-temperature polysilicon thin film transistor, so that the performance of the CMOS inverter could be improved and the manufacturing complexity and cost of the CMOS could be reduced through matching the relationship between the P-type low-temperature polysilicon thin film transistor and the N-type metal-oxide thin film transistor to the relationship described above. The present invention further provides an array substrate to increase the performance of the CMOS inverter and reduce the manufacturing complexity and cost of the CMOS inverter.

Various changes or modifications can be made to the descriptions above in accordance with the technique solutions and concepts by one with ordinary skill in the art, and the changes and modifications should be within the protected scope of the claims of the present invention.

What is claimed is:

1. A CMOS inverter, comprising a P-type low-temperature polysilicon thin film transistor electrically coupled to a N-type metal-oxide thin film transistor;
wherein the P-type low-temperature polysilicon thin film transistor and the N-type metal-oxide thin film transistor satisfy the relationship below:
$${C}_{n} \frac{{W}_{n}}{{L}_{n}} {μ}_{n} = {C}_{P} \frac{{W}_{P}}{{L}_{P}} {μ}_{P} ,$$
wherein, Cₙ is a gate-insulating-layer capacitance of the N-type metal oxide thin film transistor, C_{P} is a gate-insulating-layer capacitance of the P-type low-temperature polysilicon thin film transistor,
$$\frac{{W}_{n}}{{L}_{n}}$$
is a channel width-length ratio of the N-type metal-oxide thin film transistor,
$$\frac{{W}_{P}}{{L}_{P}}$$
is the channel width-length ratio of the P-type low-temperature polysilicon thin film transistor, μₙ is a mobility of the N-type metal-oxide thin film transistor, and μ_{P} is the mobility of P-type low-temperature polysilicon thin film transistor.

2. The CMOS inverter according to claim 1, wherein a gate of the P-type low-temperature polysilicon thin film transistor and a gate of the N-type metal-oxide thin film transistor both are coupled to receive an input signal;
wherein, a source of the P-type low-temperature polysilicon thin film transistor is coupled to a voltage source, a source of the N-type metal-oxide thin film transistor is coupled to ground, a drain of the P-type low-temperature polysilicon thin film transistor and a drain of the N-type metal-oxide thin film transistor both provide an output signal.

3. The COMS inverter according to claim 1, further comprising: a substrate; a first semiconducting layer formed above the substrate; a first gate insulating layer covering the first semiconducting layer and the substrate; a first metal layer formed above the first gate insulating layer; a second gate insulating layer covering the first metal layer and the first gate insulating layer; a second semiconducting layer formed above the second gate insulating layer; and a second metal layer formed above the second semiconducting layer and the second gate insulating layer.

4. The CMOS inverter according to claim 3, wherein the first semiconducting layer is a semiconducting layer of the P-type low-temperature polysilicon thin film transistor, and the second semiconducting layer is a semiconducting layer of the N-type metal-oxide thin film transistor.

5. The CMOS inverter according to claim 4, wherein, the first metal layer comprises: a first gate and a second gate disposed at intervals, wherein the first gate is disposed directly opposite to the first semiconducting layer and the second gate is disposed directly opposite to the second semiconducting layer; and
the first gate is a gate of the P-type low-temperature polysilicon thin film transistor, and the second gate is a gate of the N-type metal-oxide thin film transistor.

6. The CMOS inverter according to claim 5, wherein a first through hole and a second through hole penetrating through the first gate insulating layer and the second gate insulating layer are formed in the second gate insulating layer, and two terminals of the first semiconducting layer are exposed through the first through hole and the second through hole, respectively;
the second metal layer comprises: a first source and a second source disposed at intervals; and a first drain and a second drain formed between the first source and the second source; the two terminals of the first semiconducting layer are connected to the first source and the first drain through the first through hole and the second through hole, respectively, two terminals of the second semiconducting layer are connected to the second source and the second drain, respectively, and the first drain and the second drain are connected; and
the first source and the first drain are source and drain of the P-type low-temperature polysilicon thin film transistor, and the second source and the second drain are source and drain of the N-type metal-oxide thin film transistor.

7. The CMOS inverter according to claim 3, wherein a buffer layer is formed between the first semiconducting layer and the substrate and between the first gate insulating layer and the substrate, and an etching barrier layer is formed above the second semiconducting layer between the second source and the second drain.

8. The CMOS inverter according to claim 3, wherein materials of the first gate insulating layer and the second insulating layer each comprises at least one or combinations of silicon oxide and silicon nitride, and materials of the first metal layer and the second metal layer each comprises at least one or combinations of at least two of molybdenum, aluminum, copper, and titanium.

9. The CMOS inverter according to claim 1, wherein material of the semiconducting layer of the N-type metal-oxide thin film transistor comprises IGZO or IZO.

10. An array substrate comprising the CMOS inverter as claimed in claim 1.

11. A CMOS inverter, comprising: a P-type low-temperature polysilicon thin film transistor electrically coupled to a N-type metal-oxide thin film transistor;
wherein the P-type low-temperature polysilicon thin film transistor and the N-type metal-oxide thin film transistor satisfy the relationship below:
$${C}_{n} \frac{{W}_{n}}{{L}_{n}} {μ}_{n} = {C}_{P} \frac{{W}_{P}}{{L}_{P}} {μ}_{P}$$
wherein, Cₙ is a gate-insulating-layer capacitance of the N-type metal oxide thin film transistor, C_{P} is a gate-insulating-layer capacitance of the P-type low-temperature polysilicon thin film transistor,
$$\frac{{W}_{n}}{{L}_{n}}$$
is a channel width-length ratio of the N-type metal-oxide thin film transistor,
$$\frac{{W}_{P}}{{L}_{P}}$$
is the channel width-length ratio of the P-type low-temperature polysilicon thin film transistor, μₙ is a mobility of the N-type metal-oxide thin film transistor, and μ_{P} is the mobility of P-type low-temperature polysilicon thin film transistor;
wherein, a gate of the P-type low-temperature polysilicon thin film transistor and a gate of the N-type metal-oxide thin film transistor both are coupled to receive an input signal;
a source of the P-type low-temperature polysilicon thin film transistor is coupled to a voltage source, a source of the N-type metal-oxide thin film transistor is coupled to ground, and a drain of the P-type low-temperature polysilicon thin film transistor and a drain of the N-type metal-oxide thin film transistor both provide an output signal;
the CMOS inverter further comprises: a substrate; a first semiconducting layer formed above the substrate; a first gate insulating layer covering the first semiconducting layer and the substrate; a first metal layer formed above the first gate insulating layer; a second gate insulating layer covering the first metal layer and the first gate insulating layer; a second semiconducting layer formed above the second gate insulating layer; and a second metal layer formed above the second semiconducting layer and the second gate insulating layer;
wherein, the first semiconducting layer is a semiconducting layer of the P-type low-temperature polysilicon thin film transistor, and the second semiconducting layer is a semiconducting layer of the N-type metal-oxide thin film transistor;
wherein, the first metal layer comprises: a first gate and a second gate disposed at intervals, wherein the first gate is disposed directly opposite to the first semiconducting layer and the second gate is disposed directly opposite to the second semiconducting layer; and
the first gate is the gate of the P-type low-temperature polysilicon thin film transistor, and the second gate is the gate of the N-type metal-oxide thin film transistor.

12. The CMOS inverter according to claim 11, wherein a first through hole and a second through hole are formed in the second gate insulating layer, and two terminals of the first semiconducting layer are exposed through the first through hole and the second through hole, respectively;
wherein the second metal layer comprises:
a first source and a second source disposed at intervals; and
a first drain and a second drain formed between the first source and the second source,
wherein the two terminals of the first semiconducting layer are connected to the first source and the first drain through the first through hole and the second through hole, respectively, two terminals of the second semiconducting layer are connected to the second source and the second drain, respectively, and the first drain and the second drain are connected,
wherein the first source and the first drain are source and drain of the P-type low-temperature polysilicon thin film transistor, and the second source and the second drain are source and drain of the N-type metal-oxide thin film transistor.

13. The CMOS inverter according to claim 11, wherein a buffer layer is formed between the first semiconducting layer and the substrate and between the first gate insulating layer and the substrate, and an etching barrier layer is formed above the second semiconducting layer between the second source and the second drain.

14. The CMOS inverter according to claim 11, wherein the first gate insulating layer and the second insulating layer each comprises at least one or combinations of silicon oxide and silicon nitride, and the first metal layer and the second metal layer each comprises at least one or combinations of at least two of molybdenum, aluminum, copper, and titanium.

15. The CMOS inverter according to claim 11, wherein the semiconducting layer of the N-type metal-oxide thin film transistor comprises IGZO or IZO.
